(19) United States
(12) Patent Application Publication
(10) Pub. No.: US 2025/0279347 A1
(43) Pub. Date: Sep. 4, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Pin-Jing SU, Taichung City (TW); Wen-Yu TENG, Taichung City (TW); Liang-Yi HUNG, Taichung City (TW); Chia-Cheng CHEN, Taichung City (TW); Yu-Po WANG, Taichung City (TW)

(73) Assignee: SILICONWARE PRECISION INDUSTRIES CO., LTD., Taichung City (TW)

(21) Appl. No.: 18/766,777

(22) Filed: Jul. 9, 2024

(30) Foreign Application Priority Data
Mar. 1, 2024 (TW) 113107590

(51) Int. Cl. H01L 23/498; H01L 21/48; H01L 23/00

(52) U.S. Cl. CPC H01L 23/49838; H01L 21/486; H01L 23/49816; H01L 23/49822; H01L 23/562; H01L 24/08; H01L 2224/08225; H01L 2924/1815

(57) ABSTRACT

Provided is an electronic package including a carrier structure and a packaging module disposed on the carrier structure by a plurality of conductive members. The packaging module includes a plurality of circuit layers and a plurality of conductive vias, wherein the plurality of conductive vias are electrically connected to two of the circuit layers respectively, and a central axis of each of the conductive vias is deviated from a central axis of each of the conductive members. By the implementation of the present disclosure, the stresses or the external forces exerted on the conductive members can be prevented from being directly transferred to the conductive vias which would otherwise cause the conductive vias to tilt or even the electronic package to fail, such that the reliability of the electronic package can be enhanced.

### BACKGROUND

### 1. Technical Field

The present disclosure relates to a semiconductor packaging technology, and more particularly, to an electronic package and a manufacturing method thereof.

### 2. Description of Related Art

With the evolution of technology, the development trend of electronic products begins to move towards heterogeneous integration. To this end, the structure and technology of multi-chip module (MCM) or multi-chip package (MCP) gradually rise. In the process of disposing a semiconductor device on a substrate, an active surface of the chip is usually electrically connected to a circuit structure by a plurality of solder bumps, and multiple conductive elements as input/output (I/O) terminals are implanted on the other surface of the circuit structure, so that the semiconductor device is disposed on the substrate through the conductive elements.

As shown in FIG. 1A, a conventional semiconductor package 1 bonds a plurality of semiconductor chips 10 onto a redistribution structure 11, the semiconductor chips 10 are then covered with an encapsulant 15, and the redistribution structure 11 is disposed on a packaging substrate 12 by a plurality of conductive elements 111, and the packaging substrate 12 can be connected to a circuit board (not shown) by a plurality of solder balls 13. By the manner of packaging multiple semiconductor chips 10 into a single structure, the semiconductor package 1 has a larger number of input/output (I/O) terminals, and the computing/processing of the semiconductor package 1 can be greatly increased, and also the delay time of signal transmission can be reduced. Therefore, it can be applied to high-end products with high circuit density/high transmission speed/high stack count/large size design.

However, as shown in FIG. 1B which enlarges an area A in FIG. 1A, in the aforementioned redistribution structure 11 in the semiconductor package 1, the position of the conductive vias 112 is often disposed on conductive bumps 14 such as conductive pillars, so that the stress generated in the underlying structure or the external force is easily transmitted directly to the conductive vias above it through the conductive bumps 14, which causes the conductive vias to become tilt, or more even causing a break of the redistribution structure 11 resulting in electrical failure of the semiconductor package 1 and reducing the reliability of the semiconductor package 1.

Therefore, there is a need for a solution that addresses the aforementioned shortcomings in the prior art.

### SUMMARY

In view of the aforementioned shortcomings of the prior art, the present disclosure provides an electronic package, which comprises: a carrier structure; and a packaging module is disposed on the carrier structure by a plurality of conductive members, and the packaging module comprises a plurality of circuit layers and a plurality of conductive vias; wherein the plurality of conductive vias are electrically connected to two of the plurality of circuit layers respectively, and a central axis of each of the plurality of conductive vias is deviated from a central axis of each of the plurality of conductive members.

The present disclosure also provides a method of manufacturing an electronic package, the method comprises: providing a packaging module comprising a plurality of circuit layers and a plurality of conductive vias; and disposing the packaging module on a carrier structure by a plurality of conductive members, wherein the plurality of conductive vias are electrically connected to two of the plurality of circuit layers respectively, and a central axis of each of the plurality of conductive vias is deviated from a central axis of each of the plurality of conductive members.

In the aforementioned electronic package and method, a projection of each of the plurality of conductive vias is completely deviated from a cross section of each of the plurality of conductive members.

In the aforementioned electronic package and method, each of the conductive members has a width, and the central axis of the conductive via is offset from the central axis of the conductive member by a distance of ¼ to ½ of the width.

In the aforementioned electronic package and method, the carrier structure is a substrate, an interposer, a lead frame or a chip.

In the aforementioned electronic package and method, each of the plurality of conductive members is in a shape of a column.

In the aforementioned electronic package and method, each of the plurality of conductive members further comprises a conductive bump.

In the aforementioned electronic package and method, at least one of the plurality of circuit layers is a redistribution layer.

In the aforementioned electronic package and method, the plurality of circuit layers are electrically connected to the carrier structure by the plurality of conductive members.

In the aforementioned electronic package and method, the package module comprises at least one semiconductor chip.

As can be understood from the above, in the electronic package and manufacturing method thereof of the present disclosure, the central axis of each conductive via is mainly designed to deviate from the central axis of each conductive member to avoid the stress or external force exerted on the conductive members directly transferring to the conductive vias which causing the conductive vias to tilt or even causing the electronic package to fail, such that the reliability of the electronic package can be improved.

### BRIEF DESCRIPTION OF THE DRAWINGS

FIG. 1A is a schematic cross-sectional view of a conventional packaging structure.

FIG. 1B is a partial enlarged view of area A in FIG. 1A.

FIG. 2A to FIG. 2C-1 are schematic cross-sectional views of an embodiment of the manufacturing method of the electronic package of the present disclosure.

FIG. 2C-2 is a partial cross-sectional schematic diagram of another embodiment of the manufacturing method of the electronic package of the present disclosure.

FIG. 2C-3 is a partial cross-sectional schematic diagram of further another embodiment of the manufacturing method of the electronic package of the present disclosure.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “first,” “second,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

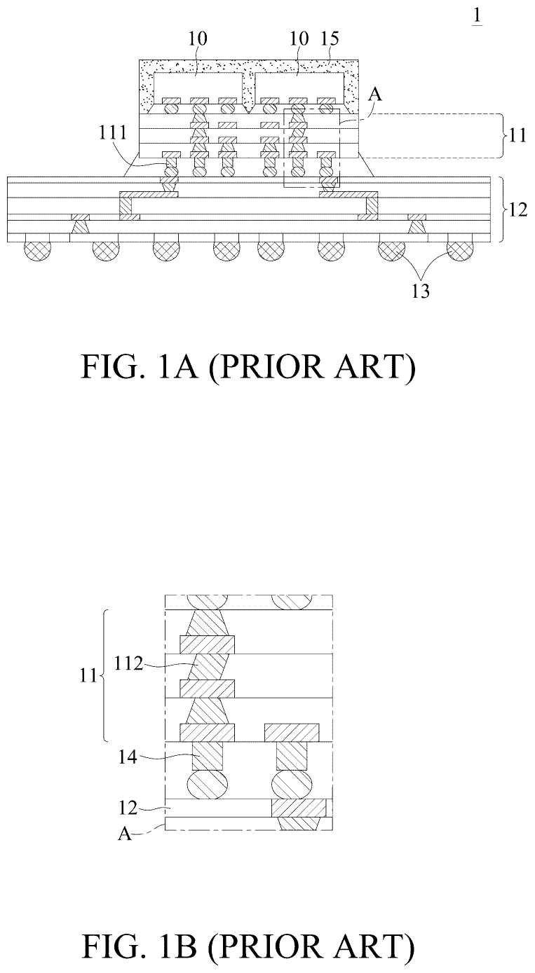

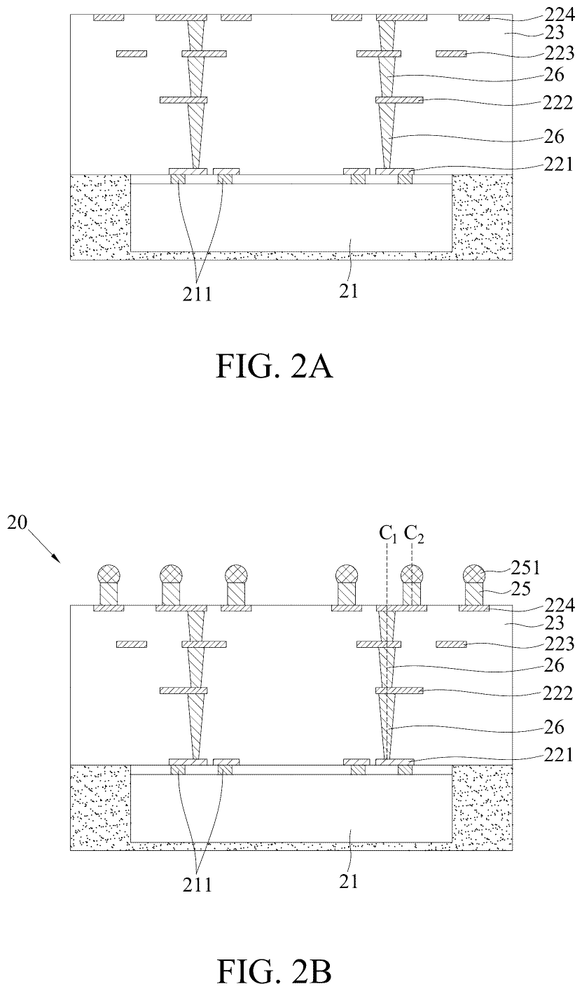

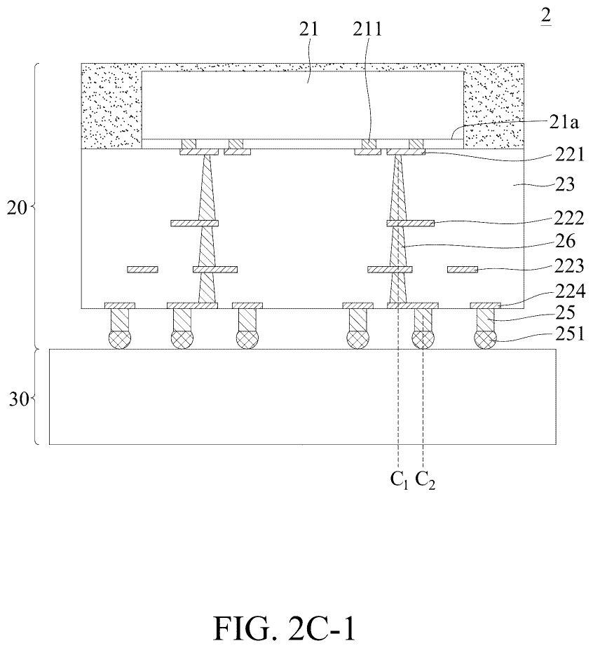

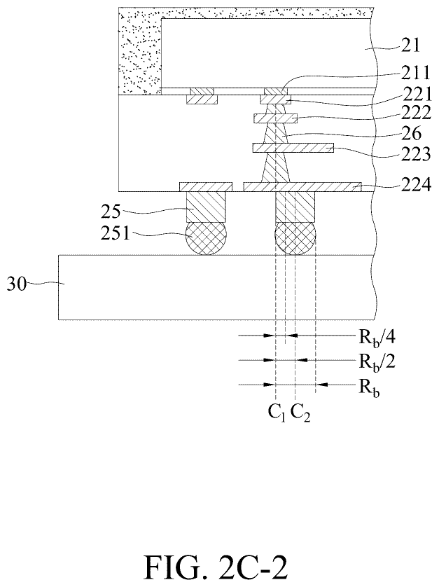

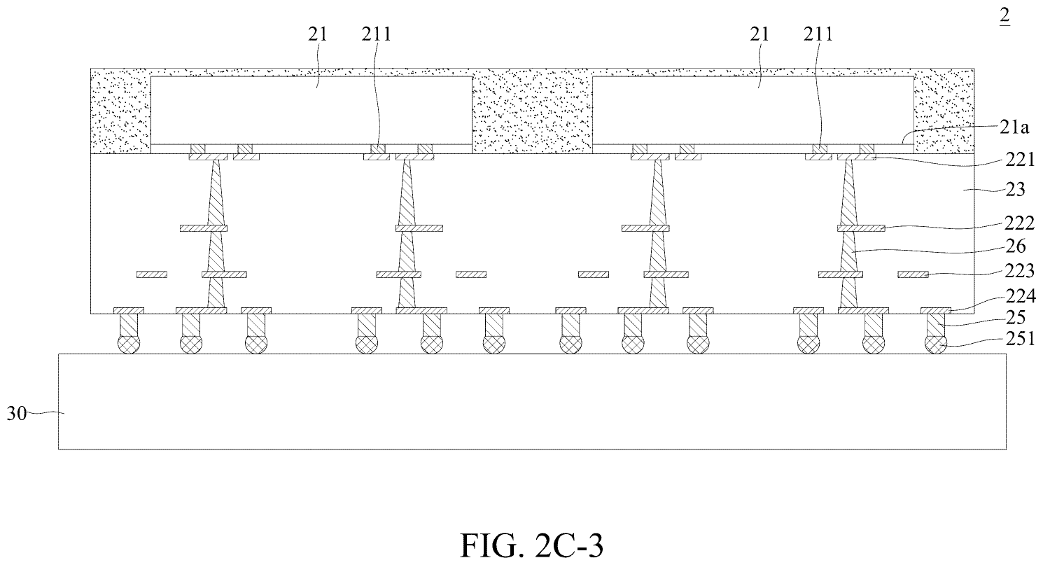

FIG. 2A to FIG. 2C-1 are schematic cross-sectional views of an embodiment of the manufacturing method of the electronic package of the present disclosure.

First, a packaging module 20 is provided. As shown in FIG. 2A, the packaging module 20 comprises a plurality of circuit layers 221, 222, 223 and 224 disposed above at least one electronic element 21, and a dielectric material 23 covering the circuit layers 221, 222, 223 and 224. In this embodiment, a semiconductor chip is served as the electronic element 21 for example. The electronic element 21 (a semiconductor chip) has an active surface 21a, and a plurality of electrical connection pads 211 are provided on the active surface 21a, and the circuit layer 221 achieves the electrical connection with the electronic element 21 by the electrical connection pads 211.

In this embodiment, disposing four circuit layers 221, 222, 223 and 224 as an example of a plurality of circuit layers, but the present disclosure is not limited to as such. A plurality of conductive vias 26 are respectively provided between the circuit layer 221 and the circuit layer 222, between the circuit layer 222 and the circuit layer 223, and between the circuit layer 223 and the circuit layer 224. The conductive vias 26 are electrically connected to the circuit layer 221 and the circuit layer 222, the circuit layer 222 and the circuit layer 223, and the circuit layer 223 and the circuit layer 224 respectively.

Next, as shown in FIG. 2B, a plurality of conductive members 25 are disposed on the circuit layer 224. The conductive members 25 are electrically connected to the circuit layer 224 respectively. A central axis C₂ of each conductive member 25 and a central axis C₁ of each conductive via 26 are offset from each other, that is, each conductive member 25 is not located directly above any conductive via 26.

As shown in FIG. 2C-1, finally, the formed packaging module 20 is turned over and placed on a carrying structure 30 by the plurality of conductive members 25 thereof to obtain the electronic package 2 illustrated in this embodiment.

In the electronic package 2 produced by the above-mentioned manufacturing method, the central axis C₁ of each conductive via 26 is offset from the central axis C₂ of each conductive member 25. Therefore, when the end of any conductive member 25 is subjected to stress or external force, these forces will not be directly transmitted to each conductive via 26 along the conductive member 25, let alone be transmitted across the circuit layers. 224, 223, 222 and 221. This can prevent external force or stress from being transmitted to each conductive via 26 through the conductive member 25 and causing each conductive via 26 to tilt or be deformed, thereby causing failure of the electronic package 2 and causing poor reliability.

Hereinafter, the specific implementation details of the manufacturing method of the electronic package 2 of the present disclosure will be further described.

As shown in FIG. 2B and FIG. 2C-1, in some embodiments, a projection of the conductive via 26 at a position of the conductive member 25 is completely deviated from a cross-section of the conductive member 25. In such a structure, since the conductive via 26 is completely deviated from an extension range of the cross section of the conductive member 25, the effect of preventing external force or stress from being transmitted from the conductive member 25 to the conductive via 26 becomes better.

In some other embodiments as shown in FIG. 2C-2, each conductive member 25 can be designed with a width R_{b}, and the central axis C₁ of the conductive via 26 is offset from the center axis C₂ of the conductive member 25 by a distance of a range between R_{b}/4 and R_{b}/2. Such a design can still reduce the degree to which the external force or stress on the conductive member 25 is directly and completely transmitted to the conductive via 26 to avoid problems such as tilting. However, the above two structural designs with different relative positions of the conductive vias 26 and the conductive members 25 can also be used in the same electronic package 2 based on the conditions of different parts, but the present disclosure is not limited to as such.

In some embodiments, the carrier structure 30 is a substrate, such as a silicon substrate, a glass substrate, or a substrate with any other suitable material. In addition, the carrier structure 30 can also be a lead frame or an interposer. The type of the carrier structure 30 completely depends on the characteristics of the final product and/or the requirements of the manufacturing process, but the present disclosure is not limited to as such.

In some other embodiments, the carrier structure 30 is a semiconductor chip, thereby forming a stacked multi-chip packaging structure.

In some embodiments, the conductive member 25 may be a copper pillar or other conductive material pillar which may be a square pillar, a cylinder or other cross-sectional shapes, or may also be a solder bump. This completely depends on the mechanical properties or electrical properties of the final product and/or the requirements of the manufacturing process, and is not specific.

In some embodiments, each conductive member 25 further includes a conductive bump 251 disposed at an end thereof. The conductive bumps 251, for example, are solder balls.

And the packaging module 20 is bonded to the carrier structure 30 by the conductive members 25 and the conductive bumps 251.

In some embodiments, at least one of the circuit layers 221, 222, 223 and 224 is a redistribution layer (RDL). In this embodiment, a material for forming the circuit layers 221, 222, 223, and 224 is a metal such as copper or any other suitable conductive material. It can be understood that the circuit layers 221, 222, 223 and 224 can be formed of the same or different materials, depending on the requirements and design, but the present disclosure is not limited to as such.

A material of the dielectric material 23 may be polybenzoxazole (PBO), polyimide (PI), prepreg (PP) or any other suitable dielectric material, but the present disclosure is not limited to as such.

In some embodiments, the circuit layer 224 is electrically connected to the carrier structure 30 by the plurality of conductive members 25.

In addition to the packaging module 20 having merely one semiconductor chip served as its electronic element 21 as shown in the above embodiment, in some other embodiments, the packaging module 20 can also contain a plurality of semiconductor chips served as electronic elements 21 as shown in FIG. 2C-3 to form a structure such as a multi-chip package (MCP).

This embodiment also illustrates an electronic package 2, which comprises: a carrier structure 30; and a packaging module 20 is provided on the carrier structure 30 by a plurality of conductive members 25, and the packaging module 20 comprises a plurality of circuit layers 221, 222, 223, 224 and a plurality of conductive vias 26; wherein the plurality of conductive vias 26 are respectively located between the circuit layer 221 and the circuit layer 222, between the circuit layer 222 and the circuit layer 223, and between the circuit layer 223 and the circuit layer 224 to electrically connect the circuit layer 221 and the circuit layer 222, connect the circuit layer 222 and circuit layer 223, and connect the circuit layer 223 and the circuit layer 224, and a central axis C₁ of each of the plurality of conductive vias 26 is offset from a central axis C₂ of each of the plurality of conductive members 25.

In some embodiments, a projection of the conductive via 26 is completely deviated from a cross-section of the conductive element 25.

In some embodiments, each of the conductive members 25 has a width R_{b}, and the central axis C₁ of the conductive via 26 is offset from the central axis C₂ of the conductive member 25 by a distance of a range between R_{b}/4 and R_{b}/2.

In some embodiments, the carrier structure 30 is a substrate, an interposer or a lead frame.

In some embodiments, the carrier structure 30 is a chip.

In some embodiments, the conductive member 25 is in a shape of a column.

In some embodiments, the conductive member 25 further comprises a conductive bump 251.

In some embodiments, at least one of the circuit layers 221, 222, 223 and 224 is a redistribution layer.

In some embodiments, the circuit layer 224 is electrically connected to the carrier structure 30 by the plurality of conductive members 25.

In some embodiments, the package module 20 contains at least one semiconductor chip.

In view of the above, in the electronic package 2 and manufacturing method thereof of the present disclosure, it is mainly designed that the central axis C₁ of each conductive via 26 is deviated from the central axis C₂ of each conductive member 25 to avoid the stress or external force exerted on the conductive members 25 directly transferring to the conductive vias 26 which causing the conductive vias 26 to tilt or even causing the electronic package 2 to fail, such that the reliability of the electronic package 2 can be improved.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure; and
a packaging module disposed on the carrier structure by a plurality of conductive members, and comprising a plurality of circuit layers and a plurality of conductive vias;
wherein the plurality of conductive vias are electrically connected to two of the plurality of circuit layers respectively, and a central axis of each of the plurality of conductive vias is deviated from a central axis of each of the plurality of conductive members.

2. The electronic package of claim 1, wherein a projection of each of the plurality of conductive vias is completely deviated from a cross section of each of the plurality of conductive members.

3. The electronic package of claim 1, wherein each of the plurality of conductive members has a width, and the central axis of the conductive via is offset from the central axis of the conductive member by a distance of ¼ to ½ of the width.

4. The electronic package of claim 1, wherein the carrier structure is a substrate, an interposer, a lead frame or a chip.

5. The electronic package of claim 1, wherein each of the plurality of conductive members is in a shape of a column.

6. The electronic package of claim 1, wherein each of the plurality of conductive members further comprises a conductive bump.

7. The electronic package of claim 1, wherein at least one of the plurality of circuit layers is a redistribution layer.

8. The electronic package of claim 1, wherein the plurality of circuit layers are electrically connected to the carrier structure by the plurality of conductive members.

9. The electronic package of claim 1, wherein the package module comprises at least one semiconductor chip.

10. A method of manufacturing an electronic package, comprising:
providing a packaging module comprising a plurality of circuit layers and a plurality of conductive vias; and
disposing the packaging module on a carrier structure by a plurality of conductive members;
wherein the plurality of conductive vias are electrically connected to two of the plurality of circuit layers respectively, and a central axis of each of the plurality of conductive vias is deviated from a central axis of each of the plurality of conductive members.

11. The method of claim 10, wherein a projection of each of the plurality of conductive vias is completely deviated from a cross section of each of the plurality of conductive members.

12. The method of claim 10, wherein each of the plurality of conductive members has a width, and the central axis of the conductive via is offset from the central axis of the conductive member by a distance of ¼ to ½ of the width.

13. The method of claim 10, wherein the carrier structure is a substrate, an interposer, a lead frame or a chip.

14. The method of claim 10, wherein each of the plurality of conductive members is in a shape of a column.

15. The method of claim 10, wherein each of the plurality of conductive members further comprises a conductive bump.

16. The method of claim 10, wherein at least one of the plurality of circuit layers is a redistribution layer.

17. The method of claim 10, wherein the plurality of circuit layers are electrically connected to the carrier structure by the plurality of conductive members.

18. The method of claim 10, wherein the package module comprises at least one semiconductor chip.
